(19) United States
(12) Patent Application Publication
(10) Pub. No.: US 2026/0068440 A1
(43) Pub. Date: Mar. 5, 2026

(54) DISPLAY DEVICE

(71) Applicant: Magnolia White Corporation, Tokyo (JP)

(72) Inventor: Sho YANAGISAWA, Tokyo (JP)

(73) Assignee: Magnolia White Corporation, Tokyo (JP)

(21) Appl. No.: 19/298,219

(22) Filed: Aug. 13, 2025

(30) Foreign Application Priority Data
Sep. 2, 2024 (JP) 2024-150844

(51) Int. Cl. H10K 59/122; H10K 59/80

(52) U.S. Cl. CPC H10K 59/122; H10K 59/873

(57) ABSTRACT

According to one embodiment, a display device includes a substrate having an upper surface, an organic insulating layer provided across a display area and a surrounding area, an inorganic insulating layer covering the organic insulating layer, a lower electrode provided on the organic insulating layer, an organic layer provided on the lower electrode, an upper electrode provided on the organic layer, and a partition formed in an overhang shape and including a lower portion and an upper portion, and a dam portion surrounding the organic insulating layer, and covered with the inorganic insulating layer. A first height between the upper surface and a top portion of the dam portion is greater than a second height between the upper surface and a top portion of the upper portion.

### CROSS-REFERENCE TO RELATED APPLICATION

This application is based upon and claims the benefit of priority from Japanese Patent Application No. 2024-150844, filed Sep. 2, 2024, the entire contents of which are incorporated herein by reference.

### FIELD Embodiments described herein relate generally to a display device.

### BACKGROUND

Recently, display devices to which an organic light emitting diode (OLED) is applied as a display element have been put into practical use. In this type of display devices, a technique for suppressing decreases in reliability is required.

### BRIEF DESCRIPTION OF THE DRAWINGS

FIG. 1 is a view showing a configuration example of a display device DSP.

FIG. 2 is a diagram showing an example of the layout of subpixels SP1, SP2, and SP3 which constitute one pixel PX.

FIG. 3 is a schematic cross-sectional view of the display device DSP along the A-B line of FIG. 2.

FIG. 4 is a schematic plan view of the display device DSP for explanations on a configuration of a surrounding area SA.

FIG. 5 is a plan view showing a part of the surrounding area SA shown in FIG. 4 in an enlarged manner.

FIG. 6 is a schematic cross-sectional view of the display device DSP along the C-D line of the surrounding area SA shown in FIG. 5.

FIG. 7 is a schematic cross-sectional view showing a part of FIG. 6 in an enlarged manner.

FIG. 8 is a schematic cross-sectional view of a contact portion CT for electrically connecting a detection line DL and a detection electrode DT to each other.

FIG. 9 is a view for explanations on a manufacturing method of the display device DSP.

FIG. 10 is a view for explanations on the manufacturing method of the display device DSP.

FIG. 11 is a view for explanations on the manufacturing method of the display device DSP.

FIG. 12 is a view for explanations on the manufacturing method of the display device DSP.

FIG. 13 is a view for explanations on the manufacturing method of the display device DSP.

FIG. 14 is a view for explanations on the manufacturing method of the display device DSP.

FIG. 15 is a view for explanations on the manufacturing method of the display device DSP.

FIG. 16 is a view for explanations on the manufacturing method of the display device DSP.

FIG. 17A is a view for explanations on another manufacturing method of the display device DSP.

FIG. 17B is a view for explanations on the other manufacturing method of the display device DSP.

FIG. 18 is a cross-sectional view showing another configuration example of the display device DSP along the C-D line of the surrounding area SA shown in FIG. 5.

FIG. 19 is a cross-sectional view showing another configuration example of the display device DSP along the C-D line of the surrounding area SA shown in FIG. 5.

FIG. 20 is a cross-sectional view showing the other configuration example of the display device DSP along the C-D line of the surrounding area SA shown in FIG. 5.

### DETAILED DESCRIPTION

An object of embodiments is to provide a display device capable of suppressing decreases in reliability.

In general, according to one embodiment, a display device includes a substrate having an upper surface, an organic insulating layer facing the upper surface and provided across a display area for displaying images and a surrounding area located outside the display area, an inorganic insulating layer provided across the display area and the surrounding area and covering the organic insulating layer, a lower electrode provided on the organic insulating layer and having a peripheral portion covered with the inorganic insulating layer in the display area, an organic layer provided on the lower electrode and including a light emitting layer, an upper electrode provided on the organic layer, and a partition formed in an overhang shape and including a lower portion provided on the inorganic insulating layer, having conductivity, and contacting the upper electrode and an upper portion provided on the lower portion, and a dam portion spaced apart from the organic insulating layer, surrounding the organic insulating layer, and covered with the inorganic insulating layer. A first height between the upper surface and a top portion of the dam portion is greater than a second height between the upper surface and a top portion of the upper portion.

According to another embodiment, a display device includes a substrate, a first organic insulating layer provided across a display area for displaying images and a surrounding area located outside the display area, a second organic insulating layer covering the first organic insulating layer, an inorganic insulating layer provided across the display area and the surrounding area and covering the second organic insulating layer, a lower electrode provided on the second organic insulating layer and having a peripheral portion covered with the inorganic insulating layer in the display area, an organic layer provided on the lower electrode and including a light emitting layer, an upper electrode provided on the organic layer, a partition formed in an overhang shape and including a lower portion provided on the inorganic insulating layer, having conductivity, and contacting the upper electrode, and an upper portion provided on the lower portion, and a dam portion provided in the surrounding area, spaced apart from the second organic insulating layer, and surrounding the second organic insulating layer. The dam portion includes a first layer formed of a material equivalent to that of the first organic insulating layer, a second layer formed of a material equivalent to that of the second organic insulating layer and covering the first layer, and a third layer formed of an organic insulating material, covering the second layer, and covered with the inorganic insulating layer.

According to the embodiment, a display device capable of suppressing decreases in reliability can be provided.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

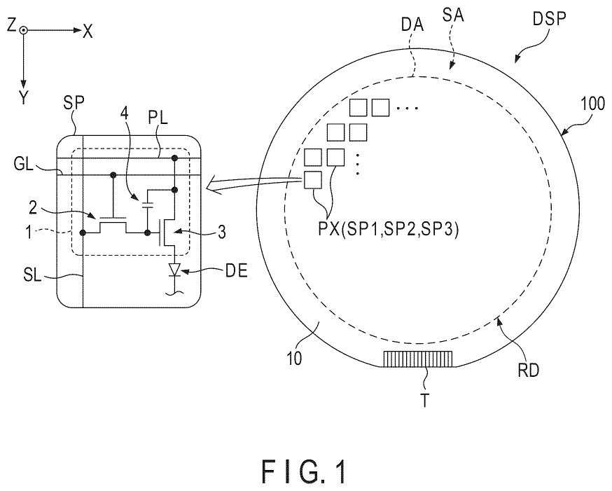

FIG. 1 is a view showing a configuration example of a display device DSP.

The display device DSP comprises a display panel 100. The display panel 100 has a display area DA for displaying images and a surrounding area SA around the display area DA on an insulating substrate 10. The substrate 10 may be either a glass substrate or a resinous substrate having flexibility.

The outer edge of at least part of the display area DA includes a round portion RD. In the illustrated example, the display area DA has a circular shape in plan view. The shape of the display area DA in plan view is not limited to the illustrated example. For example, the outer edge of the display area DA may be constituted by the combination of the round portion RD and a straight-line portion.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The round portion RD in the display area DA is a shape in a macroscopic scale. In a microscopic scale, this shape is formed by providing a plurality of pixels PX in a stair step layout.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to the display element DE. In the illustrated example, the scanning lines GL and the power line PL extend in the first direction X and the signal lines SL extend in the second direction Y.

The configuration of the pixel circuit 1 is not limited to the example shown in the figure. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display elements DE.

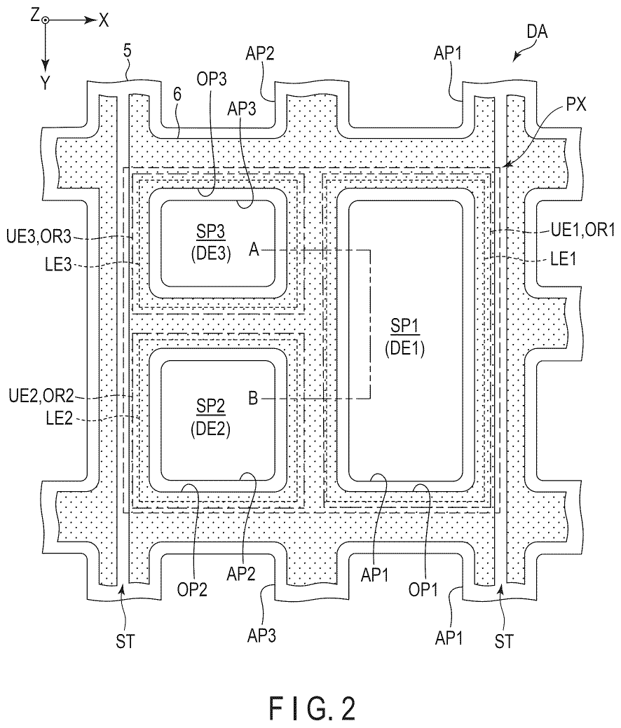

FIG. 2 is a diagram showing an example of the layout of the subpixels SP1, SP2, and SP3 which constitute one pixel PX.

In the illustrated example, the subpixels SP2 and SP3 are arranged in the second direction Y. The subpixels SP1 and SP2 are arranged in the first direction X. The subpixels SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the example of FIG. 2.

An inorganic insulating layer 5 and a partition 6 are provided in the display area DA. The inorganic insulating layer 5 has apertures AP1, AP2, and AP3 in the respective subpixels SP1, SP2, and SP3. The inorganic insulating layer 5 having these apertures AP1, AP2, and AP3 may be called a rib.

The partition 6 overlaps the inorganic insulating layer 5 in plan view. The partition 6 is formed into a grating shape surrounding the apertures AP1, AP2, and AP3. In other words, the partition 6 has respective apertures OP1, OP2, and OP3 in the subpixels SP1, SP2, and SP3 in the same manner as the inorganic insulating layer 5. The aperture OP1 overlaps the aperture AP1. The aperture OP2 overlaps the aperture AP2. The aperture OP3 overlaps the aperture AP3. The partition 6 is conductive and is electrically connected to a terminal with common voltage at the terminal portion T shown in FIG. 1.

The respective subpixels SP1, SP2, and SP3 comprise display elements DE1, DE2, and DE3 as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered with the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered with the inorganic insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the inorganic insulating layer 5 in plan view.

In the illustrated example, the outlines of the lower electrodes LE1, LE2, and LE3 are indicated by dotted lines, and the outlines of the organic layers OR1, OR2, and OR3 and the upper electrodes UE1, UE2, and UE3 are indicated by one-dot chain lines. The outer shape of each of the lower electrodes, organic layers, and upper electrodes shown in the figure does not necessarily reflect the accurate shape.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planar size of the aperture AP1, the planar size of the aperture AP2, and the planar size of the aperture AP3 differ from each other. The planar size of the aperture AP1 is greater than that of the aperture AP2. The planar size of the aperture AP2 is greater than that of the aperture AP3.

The partition 6 has a plurality of slits ST. In the illustrated example, each of the slits ST extends in the second direction Y. For example, the subpixels SP1, SP2, and SP3 constituting one pixel PX are provided between two slits ST adjacent to each other in the first direction X. The slit ST may be omitted.

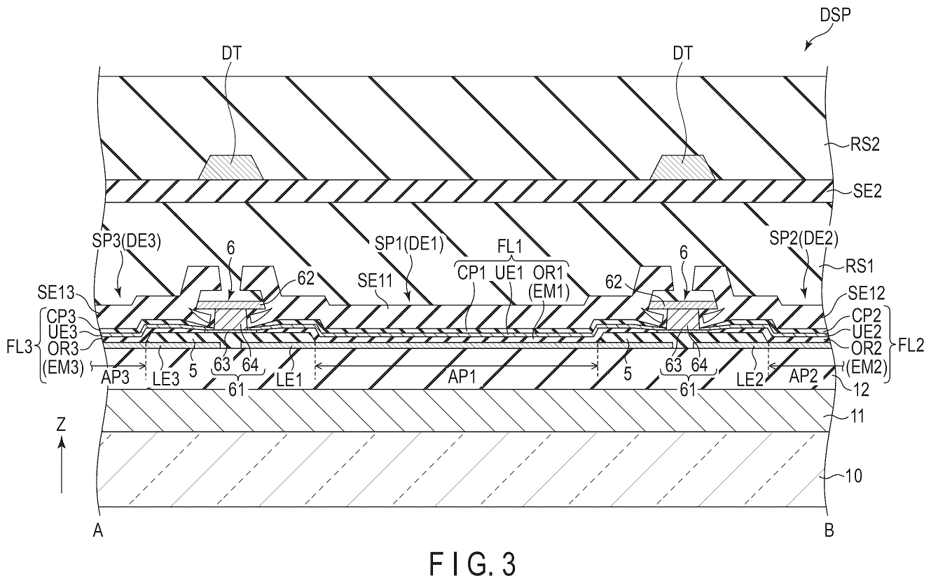

FIG. 3 is a schematic cross-sectional view of the display device DSP along the A-B line of FIG. 2.

A circuit layer 11 is provided on the substrate 10. The circuit layer 11 includes various circuits such as the pixel circuits 1 shown in FIG. 1, various lines such as the scanning lines GL, the signal lines SL, and the power lines PL, and various insulating layers.

The organic insulating layer 12 is provided on the circuit layer 11. For example, the organic insulating layer 12 is formed to planarize irregularities formed by the circuit layer 11.

The lower electrode LE1 of the subpixel SP1, the lower electrode LE2 of the subpixel SP2, and the lower electrode LE3 of the subpixel SP3 are provided on the organic insulating layer 12 and are spaced apart from each other.

The inorganic insulating layer 5 is provided on the organic insulating layer 12 and the lower electrodes LE1, LE2, and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2, and LE3 are covered with the inorganic insulating layer 5. The lower electrodes LE1, LE2, and LE3 are connected to the pixel circuits 1 of the respective subpixels SP1, SP2, and SP3 through the contact holes provided in the organic insulating layer 12. FIG. 3 omits the illustration of the contact hole in the organic insulating layer 12.

The partition 6 is formed in an overhang shape and has a lower portion 61 having conductivity and provided on the inorganic insulating layer 5 and an upper portion 62 provided on the lower portion 61.

In the illustrated example, the lower portion 61 comprises a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than that of the stem layer 64. Both end portions of the bottom layer 63 protrude relative to the side surfaces of the stem layer 64.

The upper portion 62 is provided on the stem layer 64. The upper portion 62 has the width greater than that of the stem layer 64. Both end portions of the upper portion 62 protrude relative to the side surfaces of the stem layer 64. In the present specification, the side surfaces of the stem layer 64 are assumed to be the surfaces that extend between the bottom layer 63 and the upper portion 62 of the stem layer 64. In the illustrated example, the upper portion 62 has the width greater than that of the bottom layer 63. The bottom layer 63 may have a width greater than that of the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to include, of the bottom layer 63, the surface that directly contacts the stem layer 64 and the surface that protrudes relative to the stem layer 64 and faces the upper portion 62.

In the illustrated example, the subpixel SP1 has a cap layer CP1 and a sealing layer SE11. The subpixel SP2 has a cap layer CP2 and a sealing layer SE12. The subpixel SP3 has a cap layer CP3 and a sealing layer SE13. The cap layers CP1, CP2, and CP3 function as optical adjustment layers, which improve the extraction efficiency of light emitted from the organic layers OR1, OR2, and OR3, respectively. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

The end portions of the sealing layers SE11, SE12, and SE13 are located above the partition 6. In the illustrated example, the sealing layer SE11 located on the partition 6 between the subpixels SP1 and SP2 is spaced apart from the sealing layer SE12 located on this partition 6. Further, the sealing layer SE11 located on the partition 6 between the subpixels SP1 and SP3 is spaced apart from the sealing layer SE13 located on this partition 6.

The stacked films FL1, FL2, and FL3 are not formed on the partition 6. Cavities are formed between the sealing layer SE11 and the partition 6, between the sealing layer SE12 and the partition 6, and between the sealing layer SE13 and the partition 6.

The transparent resin layer RS1 covers the partition 6 and the sealing layers SE11, SE12, and SE13. Further, the resin layer RS1 is filled into the cavity formed on the partition 6.

The sealing layer SE2 covers the resin layer RS1. The transparent resin layer RS2 is provided on the sealing layer SE2.

A detection electrode DT for achieving a touch sensor function of detecting contact or approach of an object to the display area DA is provided on the sealing layer SE2 and is covered with the resin layer RS2. For example, the detection electrode DT is a multilayer body including an aluminum layer formed of an aluminum-based material and a titanium layer formed of a titanium-based material. The touch sensor function is implemented by detecting a capacity variation in the sensor modules constituted by the detection electrode DT.

Each of the inorganic insulating layer 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃). For example, the inorganic insulating layer 5 is formed of a silicon oxynitride, and each of the sealing layers SE11, SE12, SE13, and SE2 is formed of a silicon nitride.

The lower portion 61 of the partition 6 is formed of a conductive material and is electrically connected to the upper electrodes UE1, UE2, and UE3.

The bottom layer 63 is formed of, for example, a titanium-based material such as titanium or a titanium compound. The stem layer 64 is formed of a material different from those of the bottom layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material different from that of the lower portion 61. For example, the upper portion 62 is formed of a titanium-based material such as titanium or a titanium compound or an oxide conductive material such as an indium tin oxide (ITO).

Each of the lower electrodes LE1, LE2, and LE3 is, for example, a multilayer body including a transparent layer formed of an oxide conductive material such as an indium tin oxide (ITO) and a reflective layer formed of a metal material such as silver. For example, each of the lower electrodes LE1, LE2, and LE3 is a multilayer body including a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layers EM1, EM2, EM3 are formed of materials different from each other. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. The light emitting layer EM1 may be formed of a material that emits light in a green wavelength. The light emitting layer EM2 may be formed of a material that emits light in a blue wavelength.

Each of the organic layers OR1, OR2, and OR3 includes a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body consisting of a plurality of thin films. All of the plurality of thin films are transparent and have refractive indexes different from each other.

The circuit layer 11, the organic insulating layer 12, the inorganic insulating layer 5, and the partition 6, which are illustrated, are provided across the display area DA and the surrounding area SA.

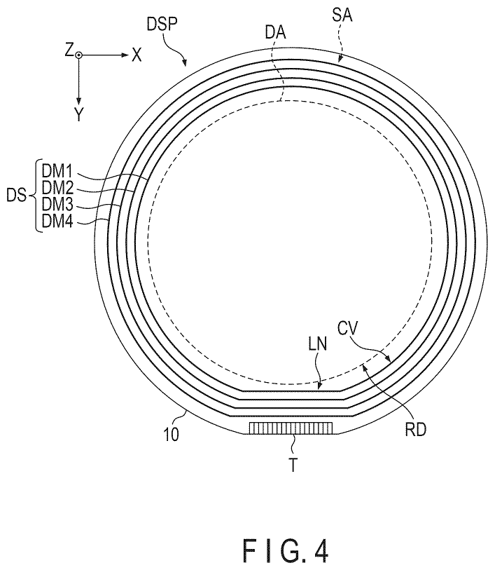

FIG. 4 is a schematic plan view of the display device DSP for explanations on the configuration of the surrounding area SA.

The display device DSP further comprises a dam structure DS provided in the surrounding area SA.

In the illustrated example, the dam structure DS comprises dam portions DM1, DM2, DM3, and DM4 in circular shapes.

The dam portion DM1 is formed to surround the display area DA. The dam portion DM2 is formed to surround the dam portion DM1. The dam portion DM3 is formed to surround the dam portion DM2. The dam portion DM4 is formed to surround the dam portion DM3.

Each of the dam portions DM1, DM2, DM3, and DM4 has an arcuate curved-line portion CV and a straight-line portion LN connected to both end portions of the curved-line portion CV. For example, the curved-line portion CV is formed along the round portion RD of the display area DA. For example, the straight-line portion LN is located between the display area DA and the terminal portion T and extends along the first direction X.

The shapes of the dam portions DM1, DM2, DM3, and DM4 are not limited to the illustrated examples.

The number of the dam portions that the dam structure DS comprises may be three or less or five or more.

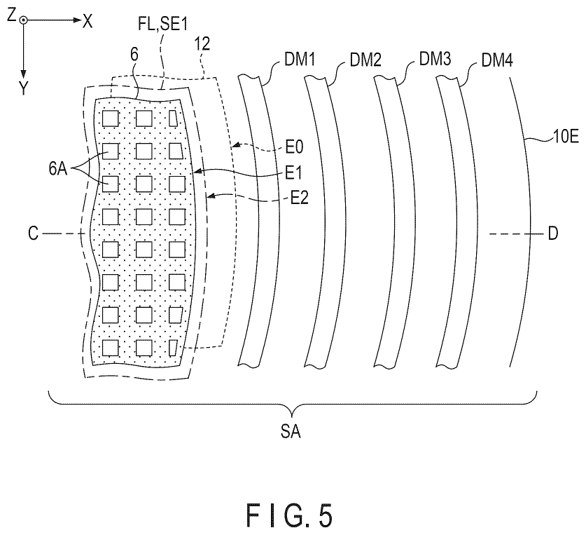

FIG. 5 is a plan view showing a part of the surrounding area SA shown in FIG. 4 in an enlarged manner.

The organic insulating layer 12 is provided in the surrounding area SA as well. The organic insulating layer 12 is provided inside the dam portion DM1. That is, the dam portion DM1 surrounds the organic insulating layer 12. An edge portion E0 of the organic insulating layer 12 is spaced apart from the dam portion DM1.

The dam portions DM1, DM2, DM3, and DM4 are located between the edge portion E0 and an edge portion 10E of the substrate 10. The dam portion DM2 is spaced apart from the dam portion DM1, the dam portion DM3 is spaced apart from the dam portion DM2, and the dam portion DM4 is spaced apart from the dam portion DM3.

The partition 6 extends in the surrounding area SA and entirely overlaps the organic insulating layer 12 in plan view. That is, an edge portion E1 of the partition 6 is located above the organic insulating layer 12. The partition 6 has a plurality of apertures 6A in the illustrated example. The plurality of apertures 6A are arranged in a matrix in the first direction X and the second direction Y.

In the illustrated example, the stacked film FL and the sealing layer SE1 are provided in the surrounding area SA. Here, the stacked film FL is any one of the stacked films FL1, FL2, and FL3 shown in FIG. 3. Here, the sealing layer SE1 is any one of the sealing layers SE11, SE12, and SE13 shown in FIG. 3. The stacked film FL and the sealing layer SE1 entirely overlap the organic insulating layer 12 in plan view. That is, an edge portion E2 of the stacked film FL and the sealing layer SE1 is located above the organic insulating layer 12.

The partition 6, the stacked film FL, and the sealing layer SE1 are provided inside the dam portion DM1. That is, the dam portion DM1 surrounds the partition 6, the stacked film FL, and the sealing layer SE1. In the illustrated example, the edge portions E0, E1, and E2 are spaced apart from the dam portion DM1 and are formed in the same arcuate shape as that of the dam portion DM1. The edge portion E2 is located between the edge portions E1 and E0.

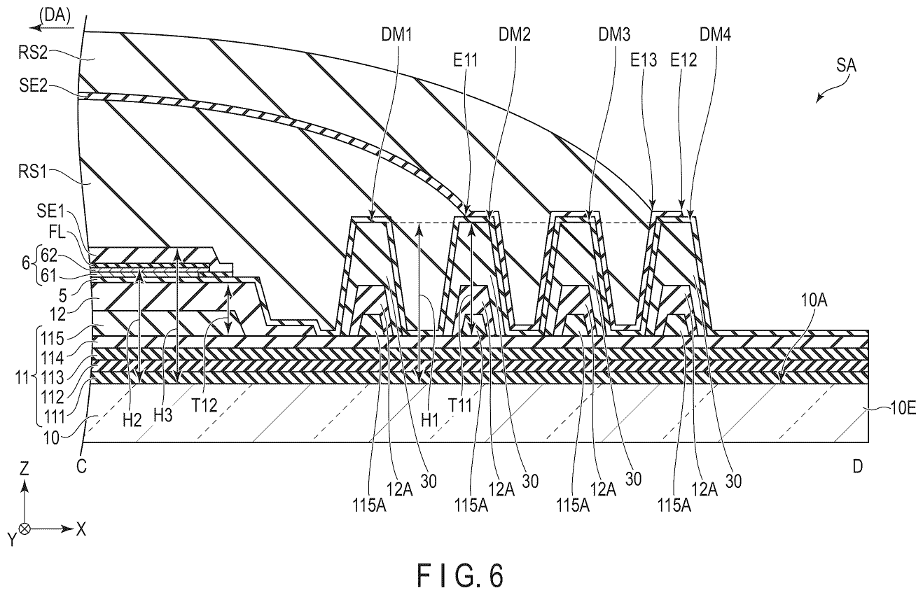

FIG. 6 is a schematic cross-sectional view of the display device DSP along the C-D line of the surrounding area SA shown in FIG. 5.

The circuit layer 11 shown in FIG. 3 comprises insulating layers 111, 112, 113, 114, and 115.

The insulating layer 111 is provided on the substrate 10. The insulating layer 112 is provided on the insulating layer 111. The insulating layer 113 is provided on the insulating layer 112. The insulating layer 114 is provided on the insulating layer 113. The insulating layer 115 is provided on the insulating layer 114. The insulating layers 111, 112, 113, and 114 are formed of inorganic insulating materials, extend to the edge portion 10E of the substrate 10, and are provided directly under the dam portions DM1, DM2, DM3, and DM4. The insulating layer 115 is formed of an organic insulating material and is covered with the organic insulating layer 12. The insulating layer 115 is spaced apart from the dam portion DM1. The organic insulating layer 12 extends between the insulating layer 115 and the dam portion DM1.

The inorganic insulating layer 5 covers the organic insulating layer 12. The inorganic insulating layer 5 covers the insulating layer 114 between the organic insulating layer 12 and the dam portion DM1. The partition 6 extending in the surrounding area SA is shown in simplified manner. This partition 6 is provided on the inorganic insulating layer 5. The stacked film FL is provided on the upper portion 62 of the partition 6 and is also provided on the inorganic insulating layer 5 between the partition 6 and the dam portion DM1. That is, the stacked film FL is divided by the partition 6. This blocks the path of moisture intrusion through the stacked film FL.

The sealing layer SE1 covers the stacked film FL overlapping the partition 6 and the stacked film FL overlapping the inorganic insulating layer 5. Each of the partition 6, the stacked film FL, and the sealing layer SE1 is located directly above the area where the insulating layer 115 and the organic insulating layer 12 overlap.

Each of the dam portions DM1, DM2, DM3, and DM4 is provided on the insulating layer 114 and is covered with the inorganic insulating layer 5. The inorganic insulating layer 5 covers the insulating layer 114 between the dam portions DM1 and DM2, between the dam portions DM2 and DM3, between the dam portions DM3 and DM4, and between the dam portion DM4 and the edge portion 10E.

In the illustrated example, each of the dam portions DM1, DM2, DM3, and DM4 comprises a first layer 115A, a second layer 12A, and a third layer 30.

The first layer 115A is formed at the same time as the insulating layer 115 using the same material as the insulating layer 115 and has the same thickness as the insulating layer 115. The second layer 12A is formed at the same time as the organic insulating layer 12 using the same material as the organic insulating layer 12 and has the same thickness as the organic insulating layer 12. The third layer 30 is formed of an organic insulating material. The thickness corresponds to the length along the third direction Z.

The first layer 115A is provided on the insulating layer 114. The second layer 12A covers the first layer 115A. The third layer 30 covers the second layer 12A and is covered with the inorganic insulating layer 5. The first layer 115A, the second layer 12A, and the third layer 30 are all formed of the same type of organic insulating material, for example, a polyimide.

The dam portions DM1, DM2, DM3, and DM4 have the same thickness, a thickness T11. Here, the thickness T11 corresponds to the distance along the third direction Z between the upper surface of the insulating layer 114 and the top portion of the dam portion (the top portion of the third layer 30). That is, the thickness T11 corresponds to the sum of the thickness of the first layer 115A, the thickness of the second layer 12A, and the thickness of the third layer 30.

In contrast, no insulating layer corresponding to the third layer 30 is provided between the organic insulating layer 12 and the inorganic insulating layer 5. A sum T12, which is the sum of the thickness of the insulating layer 115 and the thickness of the organic insulating layer 12 is smaller than the thickness T11 of the dam portion (T11>T12). In one example, the thickness of the first layer 115A is approximately 1.5 μm, the thickness of the second layer 12A is approximately 3 μm, the thickness of the third layer 30 is 2 to 3 μm, and the thickness T11 is 1.4 times or more than the thickness T12.

First heights H1 along the third direction Z between the upper surface 10A of the substrate 10 and the top portions of the respective dam portions DM1, DM2, DM3, and DM4 are equivalent to each other and greater than a second height H2 along the third direction between the upper surface 10A and the top portion of the upper portion 62 (H1>H2).

The first height H1 is also greater than a third height H3 along the third direction Z between the upper surface 10A and the top portion of the sealing layer SE1 (H1>H3).

The resin layer RS1 covers the sealing layer SE1, is provided on the inorganic insulating layer 5, and is filled between the organic insulating layer 12 and the dam portion DM1 and between the dam portions DM1 and DM2. An edge portion E11 of the resin layer RS1 overlaps the dam portion DM2. In the illustrated example, the edge portion E11 overlaps the top portion of the dam portion DM2. Further, the upper surface of the resin layer RS1 is a convex in the surrounding area SA and is formed as a smooth surface including almost no local recess portions.

This resin layer RS1 is formed by application of a liquid organic insulating material. The dam portions DM1 and DM2 have function of damming the spread of the applied organic insulating material. When the thickness T11 of the dam portions DM1 and DM2 is equal to the thickness T12 in a comparative example, the illustrated dam portions DM1 and DM2 have a higher damming capacity than those of the comparative example. Therefore, even if an amount of the organic insulating material greater than that in the comparative example is applied, the dam portions DM1 and DM2 can completely prevent the spread of the organic insulating material. Further, a greater amount of the organic insulating material can be applied. Thus, sufficient amount of the organic insulating material can be filled between the organic insulating layer 12 and the dam portion DM1, and between the dam portions DM1 and DM2. This suppresses the insufficient application of organic insulating materials and the formation of undesirable recess portions in the resin layer RS1.

The sealing layer SE2 covers the resin layer RS1. The sealing layer SE2 extends outward beyond the edge portion E11 of the resin layer RS1 and contacts the inorganic insulating layer 5 at the position overlapping the dam portion DM2. In the illustrated example, the edge portion E12 of the sealing layer SE2 is located further inward than the edge portion 10E of the substrate 10 and overlaps the dam portion DM4. That is, the resin layer RS1 is surrounded by the sealing layer SE1, the inorganic insulating layer 5, and the sealing layer SE2. This configuration suppresses the moisture intrusion into the resin layer RS1.

The resin layer RS2 is provided on the sealing layer SE2 and is filled between the dam portions DM2 and DM3 and between the dam portions DM3 and DM4. In the illustrated example, the edge portion E13 of the resin layer RS2 overlaps the dam portion DM4 and is located further inward than the edge portion E12.

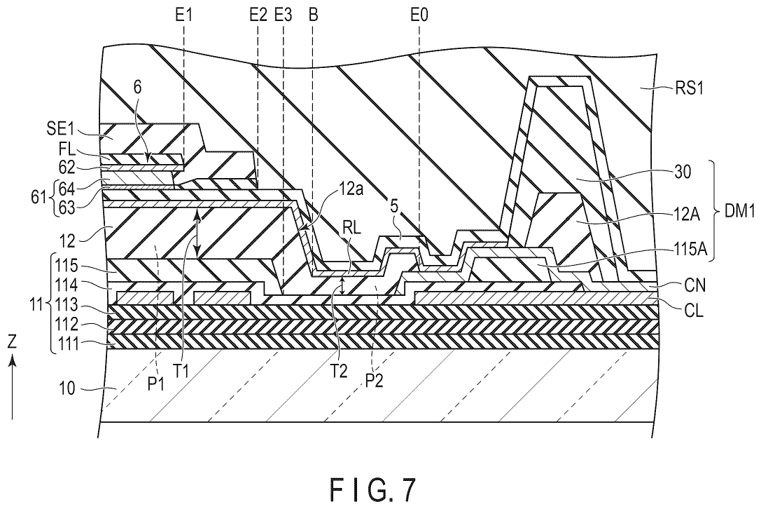

FIG. 7 is a schematic cross-sectional view showing a part of FIG. 6 in an enlarged manner.

The circuit layer 11 further comprises a power supply line CL and a connection electrode CN. The power supply line CL is provided on the insulating layer 113. Further, a portion of the power supply line CL is covered with the insulating layer 114. The power supply line CL is a line for supplying the partition 6 with common voltage. The connection electrode CN is provided on the insulating layer 114 and is also provided between the first layer 115A and the second layer 12A in the dam portion DM1, and contacts the power supply line CL.

The organic insulating layer 12 has a first portion P1 of a thickness T1 and a second portion P2 of a thickness T2. The thickness T2 is smaller than the thickness T1 (T2<T1). The second portion P2 is formed in the periphery of the first portion P1. The insulating layer 115 is provided below the first portion P1. A step portion 12a is formed in the organic insulating layer 12 in the vicinity of an edge portion E3 of the insulating layer 115. For example, a boundary B between the first portion P1 and the second portion P2 is located at the lower end portion of the step portion 12a.

A relay electrode RL is provided across the first portion P1, the second portion P2, and the step portion 12a. If the organic insulating layer 12 does not have the second portion P2, the step portion 12a becomes steeper. If the relay electrode RL is formed along the steep step portion 12a, the relay electrode RL may be subjected to deformation such as a break. On the other hand, if the organic insulating layer 12 has the second portion P2, the step portion 12a is reduced. This suppresses the deformation of the relay electrode RL.

For example, the relay electrode RL is formed of the same material as the lower electrode LE1 and is electrically connected to the partition 6 in an area, which is not illustrated. The relay electrode RL contacts the connection electrode CN between the edge portion E0 and the dam portion DM1. This electrically connects the power supply line CL and the partition 6 to each other. This relay electrode RL is covered with the inorganic insulating layer 5.

The edge portion E1 of the partition 6 and the edge portion E2 of the stacked film FL and the sealing layer SE1 are located above the first portion P1. The edge portion E1 corresponds to the end of the upper portion 62 of the partition 6. Further, each of the edge portions E1 and E2 is located on the display area DA side (the left side in the figure) relative to the edge portion E3 of the insulating layer 114.

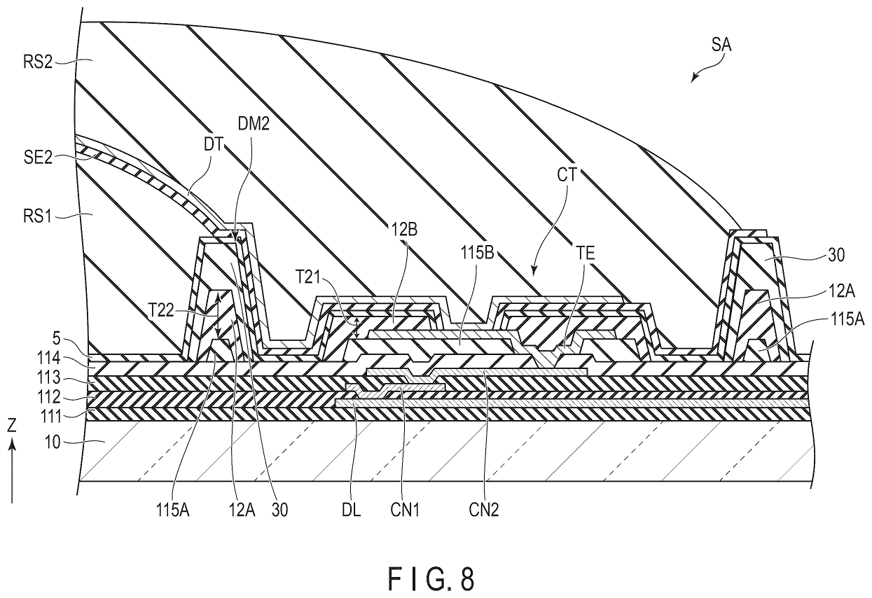

FIG. 8 is a schematic cross-sectional view of the contact portion CT for electrically connecting the detection line DL and the detection electrode DT to each other.

The contact portion CT is located further outward than the dam portion DM2. The contact portion CT comprises the detection line DL, connection electrodes CN1 and CN2, and a terminal TE. Further, an insulating layer 115B is spaced apart from the first layer 115A of the dam portion DM2 and is provided on the insulating layer 114 in the contact portion CT. An insulating layer 12B is spaced apart from the second layer 12A of the dam portion DM2 and is provided on the insulating layer 115B. The insulating layer 115B is formed at the same time as the first layer 115A using the same material as the first layer 115A. The insulating layer 12B is formed at the same time as the second layer 12A using the same material as the second layer 12A.

The detection line DL is provided between the insulating layers 111 and 112 in the surrounding area SA and is electrically connected to a detection circuit, which is not illustrated. The connection electrode CN1 is provided between the insulating layers 112 and 113 and contacts the detection line DL through a through hole in the insulating layer 112. The connection electrode CN2 is provided between the insulating layers 113 and 114 and contacts the connection electrode CN1 through a through hole in the insulating layer 113. The terminal TE is provided on the insulating layer 115B and contacts the connection electrode CN2 through the through holes in the insulating layer 114 and the insulating layer 115B. This electrically connects the terminal TE and the detection line DL to each other.

The insulating layer 12B covers a portion of the terminal TE and covers the insulating layers 114 and 115B around the terminal TE. The thickness of the insulating layer 12B differs from the second layer 12A. That is, a thickness T21 along the third direction Z of the insulating layer 12B, which overlaps the upper surface of the insulating layer 115B around the terminal TE, is smaller than a thickness T22 along the third direction Z of the second layer 12A, which overlaps the upper surface of the first layer 115A in the dam portion DM2 (T21<T22).

The inorganic insulating layer 5 and the sealing layer SE2 cover the insulating layer 12B.

The detection electrode DT is provided on the sealing layer SE2, drawn out to the contact portion CT, and contacts the terminal TE through the through holes in the insulating layer 12B, the inorganic insulating layer 5, and the sealing layer SE2. This electrically connects the detection electrode DT and the detection line DL to each other.

The detection electrode DT is covered with the resin layer RS2.

In the contact portion CT, the thickness T21 of the insulating layer 12B is smaller than the thickness T22 of the second layer 12A. Thus, in the application of a liquid organic insulating material for forming the resin layer RS2, a sufficient amount of organic insulating materials can be filled between the contact portion CT and the dam portion DM2. This suppresses the formation of undesirable gaps in the resin layer RS2.

Further, in the resin layer RS1, the formation of undesirable recess portions are suppressed as described with reference to FIG. 6. Thus, the detection electrode DT can be formed on a smooth surface. This suppresses the deformation of the detection electrode DT such as short-circuits between adjacent detection electrodes DT. Thus, decreases in reliability can be suppressed.

Next, a manufacturing method of the display device DSP will be described.

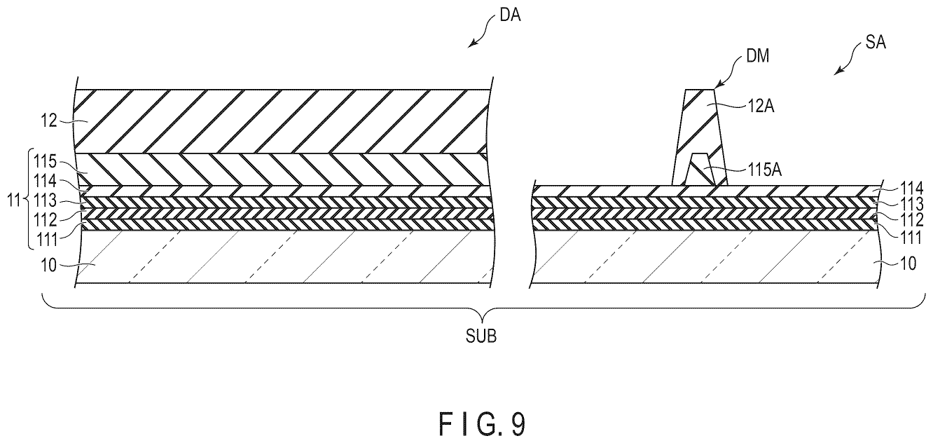

First, a processing substrate SUB is prepared as shown in FIG. 9. The step of preparing the processing substrate SUB includes a step of forming the circuit layer 11 including the insulating layers 111, 112, 113, 114, and 115 on the substrate 10 and a step of forming the organic insulating layer 12 on the insulating layer 114.

In the step of forming the insulating layer 115, an organic insulating material is first applied across the display area DA and the surrounding area SA of the processing substrate SUB. Then, a portion of the organic insulating material is cured to form the insulating layer 115 and form the first layer 115A of the dam portion DM in the surrounding area SA. At this time, the insulating layer 115B of the contact portion CT shown in FIG. 8 is formed as well. Here, the dam portion DM corresponds to the dam portions DM1, DM2, DM3, and DM4.

In the step of forming the organic insulating layer 12, an organic insulating material is first applied across the display area DA and the surrounding area SA of the processing substrate SUB. Then, a portion of the organic insulating material is cured to form the organic insulating layer 12 and form the second layer 12A of the dam portion DM in the surrounding area SA. At this time, the first portion P1 and the second portion P2 shown in FIG. 7 and the insulating layer 12B of the contact portion CT shown in FIG. 8 are formed as well.

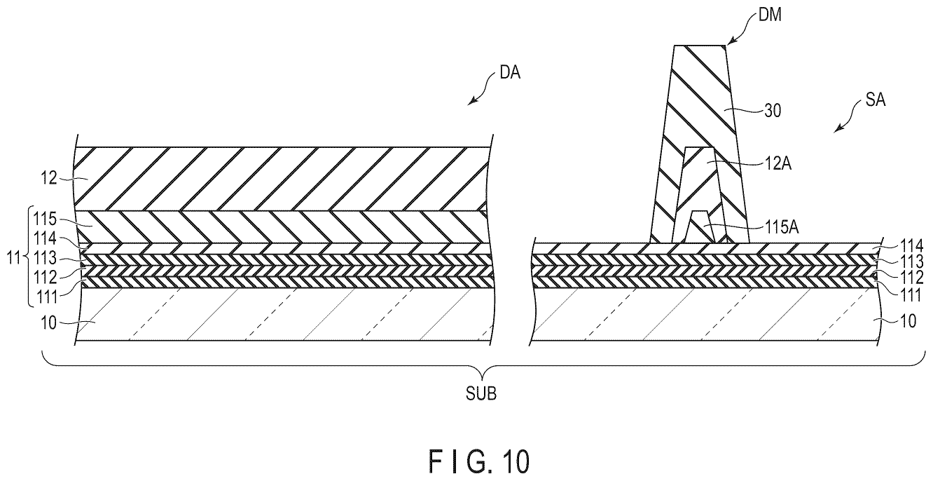

Next, the third layer 30 of the dam portion DM is formed in the surrounding area SA as shown in FIG. 10. In the step of forming the third layer 30, an organic insulating material is first applied across the display area DA and the surrounding area SA of the processing substrate SUB. Then, the organic insulating material in a portion of the surrounding area SA is cured to form the third layer 30 of the dam portion DM. The applied organic insulating material is removed in the display area DA.

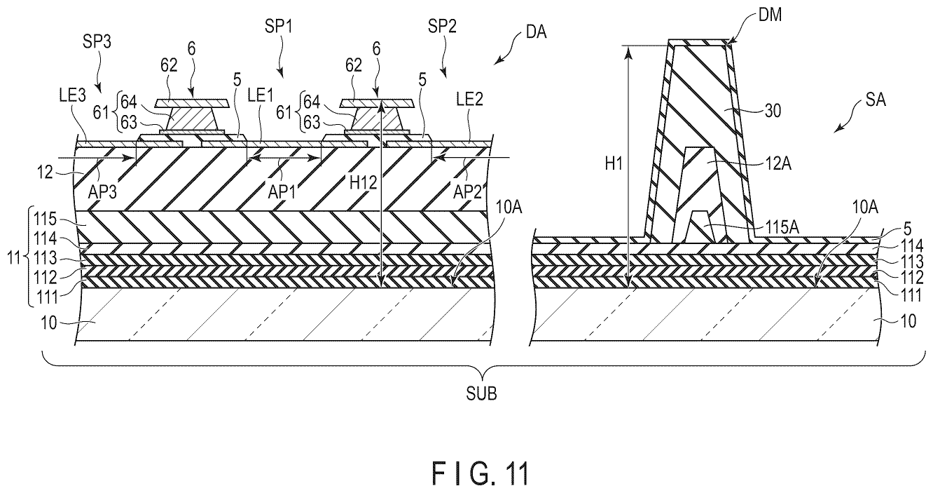

Next, the lower electrode LE1 of the subpixel SP1, the lower electrode LE2 of the subpixel SP2, and the lower electrode LE3 of the subpixel SP3 are formed on the organic insulating layer 12 in the display area DA as shown in FIG. 11. Then, the inorganic insulating layer 5 having the apertures AP1, AP2, and AP3 overlapping the respective lower electrodes LE1, LE2, and LE3, and the partition 6 having the lower portion 61 located on the inorganic insulating layer 5 and the upper portion 62 located on the lower portion 61 are formed. The partition 6 may be formed after the formation of the inorganic insulating layer 5 having the apertures AP1, AP2, and AP3. Alternatively, the apertures AP1, AP2, and AP3 may be formed on the inorganic insulating layer 5 after the formation of the partition 6. The inorganic insulating layer 5 is formed not only in the display area DA and but also in the surrounding area SA and covers the dam portion DM.

The first height H1 between the upper surface 10A of the substrate 10 and the top portion of the dam portion DM is greater than a height H12 between the upper surface 10A and the top portion of the upper portion 62 of the partition 6 in the display area DA (H1>H12). The height H12 is equivalent to the second height H2 of the surrounding area SA shown in FIG. 6.

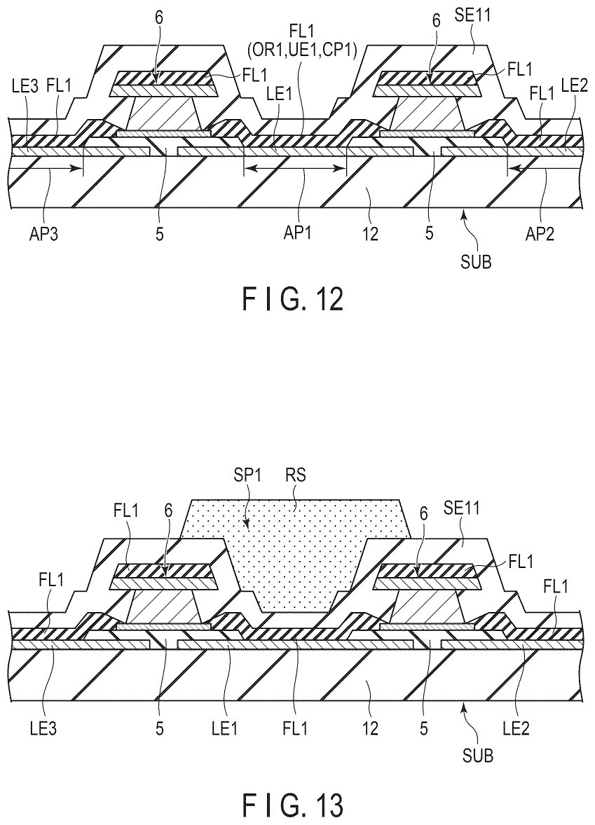

Subsequently, the display element DE1 is formed. FIG. 12 to FIG. 15 show the only cross section of the display area DA and omit the illustration of the elements below the organic insulating layer 12.

First, vapor deposition using the partition 6 as a mask is performed to form the stacked film FL1 on the processing substrate SUB as shown in FIG. 12. The stacked film FL1 includes the organic layer OR1 including the light emitting layer EM1, the upper electrode UE1, and the cap layer CP1. The organic layer OR1, the upper electrode UE1, and the cap layer CP1 are successively formed by an evaporation device in a vacuum state. The stacked film FL1 is divided by the partition 6 having an overhang shape.

Subsequently, the sealing layer SE11 continuously covering the stacked film FL1 and the partition 6 is formed. The sealing layer SE11 is formed by depositing inorganic insulating materials (for example, a silicon nitride) on the processing substrate SUB in a Chemical Vapor Deposition (CVD) device.

The stacked film FL1 and the sealing layer SE11 are formed in the substantially entire processing substrate SUB and are provided in the subpixels SP2 and SP3 as well as the subpixel SP1 in the display area DA. Though not illustrated, the stacked film FL1 and the sealing layer SE11 are formed to cover the dam portion DM in the surrounding area SA.

Subsequently, a resist RS patterned into a predetermined shape is formed on the sealing layer SE11 as shown in FIG. 13. The resist RS overlaps the subpixel SP1 and part of the partition 6 around the subpixel SP1.

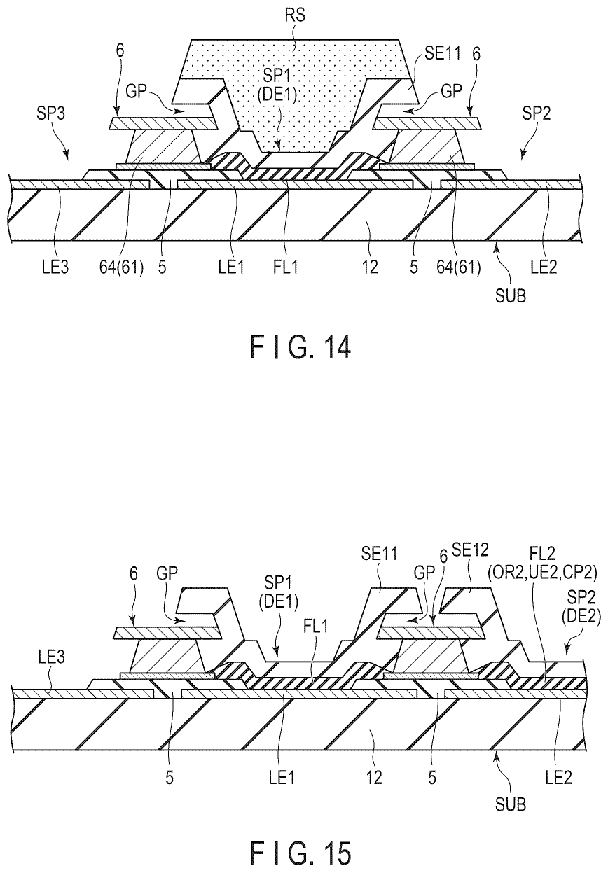

Next, patterning is performed on the sealing layer SE11 and the stacked film FL1 using the resist RS as a mask as shown in FIG. 14. After removing the sealing layer SE11 exposed from the resist RS by performing various etching using the resist RS as a mask, the cap layer CP1, the upper electrode UE1, and the organic layer OR1 included in the stacked film FL1 are sequentially removed.

These patterning processes make the lower electrode LE2 of the subpixel SP2 and the lower electrode LE3 of the subpixel SP3 exposed. Further, the stacked film FL1 and the sealing layer SE11 are removed in the surrounding area SA as well.

Subsequently, the resist RS is removed. This process forms the display element DE1 in the subpixel SP1. Further, in the illustrated example, the stacked film FL1 stacked on the partition 6 is removed in the processes between the patterning of the stacked film FL1 and the removal of the resist RS. Thus, a gap GP is formed between the sealing layer SE11 and the partition 6.

Subsequently, the display element DE2 is formed as shown in FIG. 15. The procedure of forming the display element DE2 is the same as that of forming the display element DE1. That is, the stacked film FL2 is formed on the lower electrode LE2. The stacked film FL2 includes the organic layer OR2 including the light emitting layer EM2, the upper electrode UE2, and the cap layer CP2. Subsequently, the sealing layer SE12 is formed on the stacked film FL2. Subsequently, a resist is formed on the sealing layer SE12. Then, patterning using this resist as a mask is performed. This sequentially removes the sealing layer SE12 and the stacked film FL2 exposed from the resist. Subsequently, the resist is removed.

This process forms the display element DE2 in the subpixel SP2 and makes the lower electrode LE3 of the subpixel SP3 exposed. In the illustrated example, the stacked film FL2 on the partition 6 is removed at the time of patterning. This forms the gap GP between the sealing layer SE12 and the partition 6.

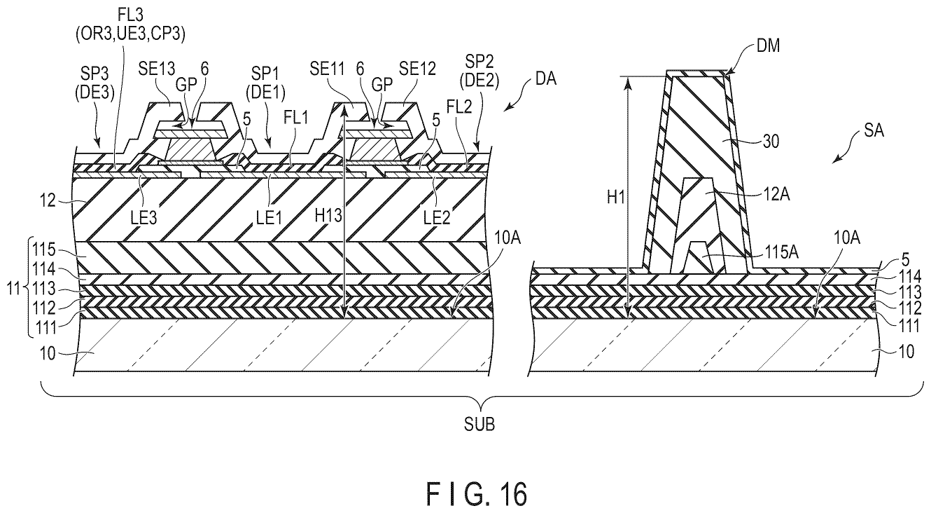

Subsequently, the display element DE3 is formed as shown in FIG. 16. The procedure of forming the display element DE3 is the same as that of forming the display element DE1. That is, the stacked film FL3 is formed on the lower electrode LE3. The stacked film FL3 has the organic layer OR3 including the light emitting layer EM3, the upper electrode UE3, and the cap layer CP3. Subsequently, the sealing layer SE13 is formed on the stacked film FL3. Subsequently, a resist is formed on the sealing layer SE13. Then, patterning using this resist as a mask is performed. This sequentially removes the sealing layer SE13 and the stacked film FL3 exposed from the resist. Subsequently, the resist is removed.

This process forms the display element DE3 in the subpixel SP3. In the illustrated example, the stacked film FL3 on the partition 6 is removed at the time of patterning. This forms the gap GP between the sealing layer SE13 and the partition 6.

The first height H1 between the upper surface 10A of the substrate 10 and the top portion of the dam portion DM is greater than a height H13 between the upper surface 10A and the top portions of the sealing layers SE11, SE12, and SE13 in the display area DA (H1>H13). The height H13 is equivalent to the third height H3 of the surrounding area SA shown in FIG. 6.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

Then, an organic insulating material is applied and cured. This forms the resin layer RS1. At this time, a sufficient amount of organic insulating materials is filled between the organic insulating layer 12 and the dam portion DM1 and between the dam portions DM1 and DM2 as described with reference to FIG. 6. This forms the resin layer RS1, which has a smooth surface.

Then, an inorganic insulating material is stacked to form the sealing layer SE2. The sealing layer SE2 is formed beyond the edge portion E11 of the resin layer RS1, contacts the inorganic insulating layer 5, and seals the resin layer RS1.

Then, a metal layer is formed on the sealing layer SE2 and patterned to form the detection electrode DT. The detection electrode DT extends beyond the dam portion DM2 and contacts the terminal TE, which is electrically connected to the detection line DL in the contact portion CT as shown in FIG. 8.

If a recess portion is formed in the base resin layer RS1 in the formation of the detection electrode DT, short-circuiting of adjacent detection electrodes DT may occur due to patterning failure of the metal layer formed in the recess portion.

As described above, the resin layer RS in the present embodiment is formed to have a smooth surface. This suppresses the patterning failure of the metal layer and the deformation of the detection electrode DT.

Then, an organic insulating material is applied and cured. This forms the resin layer RS2. At this time, the step between the dam portion DM2 and the contact portion CT is reduced. Thus, a sufficient amount of organic insulating materials is filled around the contact portion CT as described with reference to FIG. 8.

The above processes complete the display device DSP.

In the above configuration example, the dam portion DM having three layers are formed through the step of forming the first layer 115A with the insulating layer 115, the step of forming the second layer 12A with the organic insulating layer 12, and the step of forming the third layer 30.

The following describes another manufacturing method of the dam portion DM.

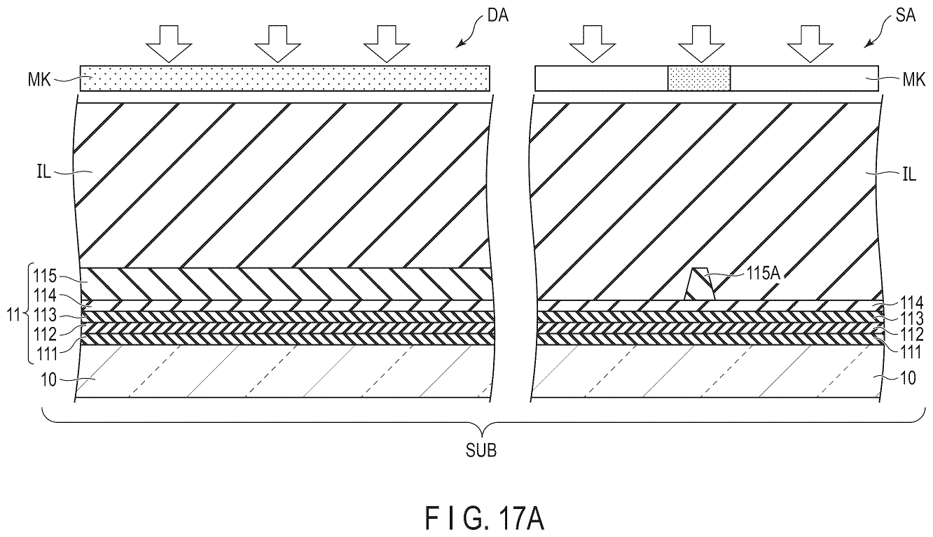

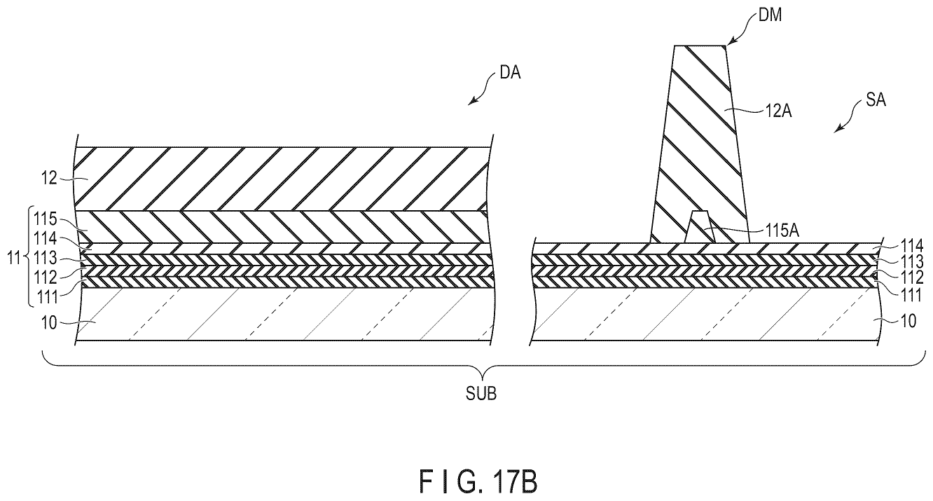

First, the processing substrate SUB is prepared as shown in FIG. 17A. In the step of preparing the processing substrate SUB, the insulating layers 111, 112, 113, and 114 are formed on the substrate 10, and then the insulating layer 115 and the first layer 115A of the dam portion DM are formed.

Thereafter, an organic insulating material IL is applied across the display area DA and the surrounding area SA of the processing substrate SUB. The organic insulating material IL is a positive-type photosensitive material and soluble in a developing solution upon exposure to light. That is, the organic insulating material IL used here can form the desired step depending on the amount of exposure.

Subsequently, the organic insulating material IL is exposed to light through a mask MK, which has partially different transmittances. With respect to the transmittance of the mask MK, for example, the transmittance is set to a maximum transmittance Tmax in the area around the dam portion DM of the surrounding area SA, to a minimum transmittance Tmin in the dam portion DM, and to an intermediate transmittance Tmid in the display area DA. The intermediate transmittance Tmid is the midpoint between the maximum transmittance Tmax and the minimum transmittance Tmin.

Next, the exposed organic insulating material IL is developed as shown in FIG. 17B. This forms the organic insulating layer 12 and the second layer 12A of the dam portion DM. The thickness of the second layer 12A is greater than the thickness of the organic insulating layer 12. Further, the organic insulating material IL is removed around the dam portion DM, and thus the insulating layer 114 is exposed. The dam portion DM formed in this manner has a two-layer structure consisting of the first layer 115A and the second layer 12A, thereby achieving the same damming function as the dam portion DM with the three-layer structure.

This manufacturing method can omit the step of forming the third layer 30 described with reference to FIG. 10, thereby reducing the manufacturing processes and manufacturing costs.

Next, other configuration examples will be described. The same constituent elements as in the above configuration example are denoted by the same reference numerals and their detailed explanations are omitted in some cases.

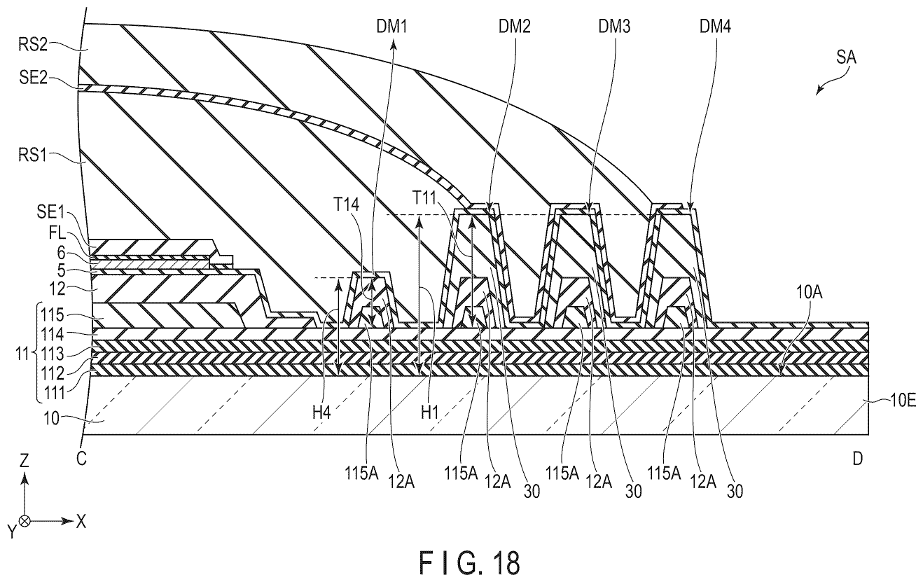

FIG. 18 is a cross-sectional view showing another configuration example of the display device DSP along the C-D line of the surrounding area SA shown in FIG. 5.

The configuration example shown in FIG. 18 differs from the configuration example shown in FIG. 6 in that, among the plurality of dam portions, a thickness T14 of the dam portion DM1, which is closer to the organic insulating layer 12 than the dam portion DM2 is, is smaller than the thickness T11 of the dam portion DM2. The dam portions DM3 and DM4 have the same thickness T11 as the dam portion DM2.

A height H4 between the upper surface 10A and the top portion of the dam portion DM1 is smaller than the height H1 between the upper surface 10A and the top portion of the dam portion DM2 (H4<H1).

In this configuration example as well, the dam portion DM2 can exhibit a high damming capacity against the applied organic insulating material in the formation of the resin layer RS1. Thus, the same effect as in the above configuration example can be achieved in the illustrated configuration example.

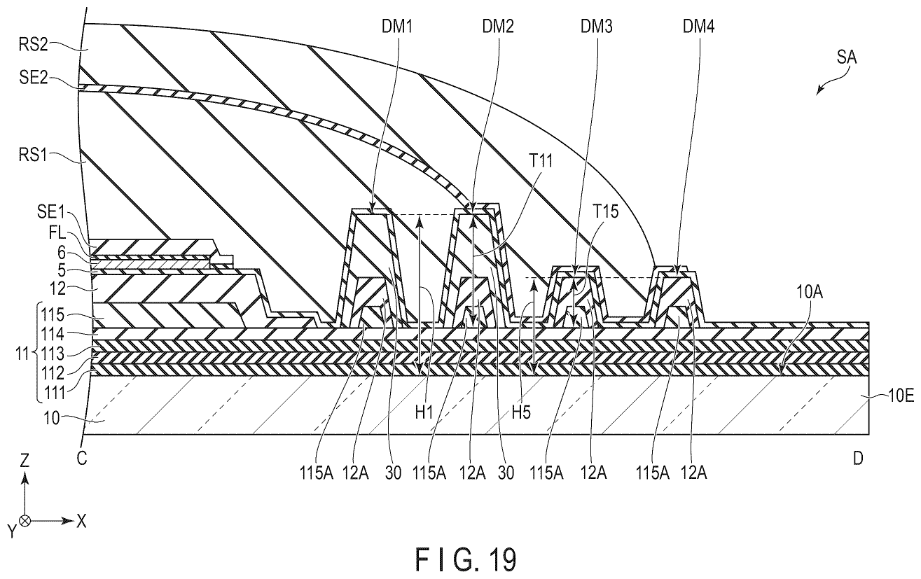

FIG. 19 is a cross-sectional view showing another configuration example of the display device DSP along the C-D line of the surrounding area SA shown in FIG. 5.

The configuration example shown in FIG. 19 differs from the configuration example shown in FIG. 6 in that, among the plurality of dam portions, a thickness T15 of the dam portions DM3 and DM4, which are closer to the edge portion 10E of the substrate 10 than the dam portion DM2 is, is smaller than the thickness T11 of the dam portion DM2. The dam portion DM1 has the same thickness T11 as the dam portion DM2.

A height H5 between the upper surface 10A and the top portion of the dam portion DM3 is smaller than the height H1 between the upper surface 10A and the top portion of the dam portion DM2 (H5<H1).

In this configuration example as well, the dam portions DM1 and DM2 can exhibit a high damming capacity against the applied organic insulating material in the formation of the resin layer RS1. Thus, the same effect as in the above configuration example can be achieved in the illustrated configuration example.

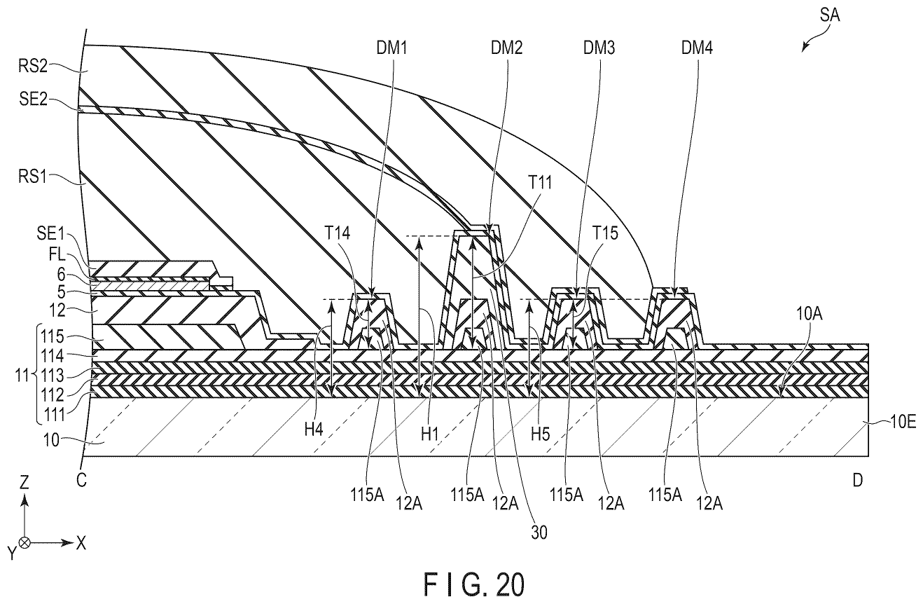

FIG. 20 is a cross-sectional view showing another configuration example of the display device DSP along the C-D line of the surrounding area SA shown in FIG. 5.

The configuration example shown in FIG. 20 differs from the configuration example shown in FIG. 19 in that the thickness T14 of the dam portion DM1 is smaller than the thickness T11 of the dam portion DM2.

The height H4 between the upper surface 10A and the top portion of the dam portion DM1 is smaller than the height H1 between the upper surface 10A and the top portion of the dam portion DM2 (H4<H1).

In this configuration example as well, the dam portion DM2 can exhibit a high damming capacity against the applied organic insulating material in the formation of the resin layer RS1. Thus, the same effect as in the above configuration example can be achieved in the illustrated configuration example.

In addition, the dam portions DM1, DM3, and DM4, which are different from the main dam portion DM2 contributing to the damming of the resin layer RS1, are made thinner. This suppresses the generation of undesirable residues of conductive materials (for example, materials forming the lower electrode, materials forming the partition, and materials forming the detection electrode) between adjacent dam portions.

In the above present embodiment, for example, the dam portion DM1 corresponds to the inner dam portion, and the dam portions DM3 and DM4 correspond to the outer dam portions.

The sealing layers SE11, SE12, and SE13 correspond to the first sealing layer, the resin layer RS1 corresponds to the first resin layer, the sealing layer SE2 corresponds to the second sealing layer, and the resin layer RS2 corresponds to the second resin layer.

The insulating layer 115 corresponds to the first organic insulating layer, and the organic insulating layer 12 corresponds to the second organic insulating layer. The insulating layer 115B corresponds to the first insulating layer, and the insulating layer 12B corresponds to the second insulating layer.

The first insulating layer 111 corresponds to the first inorganic insulating layer, the insulating layer 112 corresponds to the second inorganic insulating layer, the insulating layer 113 corresponds to the third inorganic insulating layer, and the insulating layer 114 corresponds to the fourth inorganic insulating layer.

As described above, the present embodiment can provide a display device which can suppress decreases in reliability.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device, comprising:
a substrate having an upper surface;
an organic insulating layer facing the upper surface and provided across a display area for displaying images and a surrounding area located outside the display area;
an inorganic insulating layer provided across the display area and the surrounding area and covering the organic insulating layer;
a lower electrode provided on the organic insulating layer and having a peripheral portion covered with the inorganic insulating layer in the display area;
an organic layer provided on the lower electrode and including a light emitting layer;
an upper electrode provided on the organic layer;
a partition formed in an overhang shape and comprising:
a lower portion provided on the inorganic insulating layer, having conductivity, and contacting the upper electrode; and
an upper portion provided on the lower portion; and
a dam portion spaced apart from the organic insulating layer, surrounding the organic insulating layer, and covered with the inorganic insulating layer, wherein
a first height between the upper surface and a top portion of the dam portion is greater than a second height between the upper surface and a top portion of the upper portion.

2. The display device of claim 1, further comprising:
a stacked film provided on the upper portion in the surrounding area; and
a first sealing layer formed of an inorganic insulating material and covering the stacked film in the surrounding area, wherein
the first height is greater than a third height between the upper surface and a top portion of the first sealing layer.

3. The display device of claim 2, further comprising a first resin layer covering the first sealing layer, wherein
an edge portion of the first resin layer overlaps the dam portion.

4. The display device of claim 3, further comprising an inner dam portion located between the organic insulating layer and the dam portion and spaced apart from the organic insulating layer, wherein
the first resin layer is filled between the organic insulating layer and the inner dam portion and between the inner dam portion and the dam portion.

5. The display device of claim 4, wherein
a height between the upper surface and a top portion of the inner dam portion is equivalent to the first height.

6. The display device of claim 4, wherein
a height between the upper surface and a top portion of the inner dam portion is smaller than the first height.

7. The display device of claim 3, further comprising:
a second sealing layer formed of an inorganic insulating material and covering the first resin layer;
a second resin layer provided on the second sealing layer; and
a detection electrode provided on the second sealing layer, covered with the second resin layer, and configured to detect contact or approach of an object to the display area, wherein
the second sealing layer contacts the inorganic insulating layer at a position overlapping the dam portion.

8. The display device of claim 7, further comprising an outer dam portion surrounding the dam portion, wherein
the second resin layer is filled between the dam portion and the outer dam portion.

9. The display device of claim 8, wherein
a height between the upper surface and a top portion of the outer dam portion is equivalent to the first height.

10. The display device of claim 8, wherein
a height between the upper surface and a top portion of the outer dam portion is smaller than the first height.

11. The display device of claim 10, further comprising an inner dam portion located between the organic insulating layer and the dam portion and spaced apart from the organic insulating layer, wherein
a height between the upper surface and a top portion of the inner dam portion is smaller than the first height.

12. A display device, comprising:
a substrate;
a first organic insulating layer provided across a display area for displaying images and a surrounding area located outside the display area;
a second organic insulating layer covering the first organic insulating layer;
an inorganic insulating layer provided across the display area and the surrounding area and covering the second organic insulating layer;
a lower electrode provided on the second organic insulating layer and having a peripheral portion covered with the inorganic insulating layer in the display area;
an organic layer provided on the lower electrode and including a light emitting layer;
an upper electrode provided on the organic layer;
a partition formed in an overhang shape and comprising:
a lower portion provided on the inorganic insulating layer, having conductivity, and contacting the upper electrode; and
an upper portion provided on the lower portion; and
a dam portion provided in the surrounding area, spaced apart from the second organic insulating layer, and surrounding the second organic insulating layer, wherein
the dam portion comprises:
a first layer formed of same material as that of the first organic insulating layer;
a second layer formed of same material as that of the second organic insulating layer and covering the first layer; and
a third layer formed of an organic insulating material, covering the second layer, and covered with the inorganic insulating layer.

13. The display device of claim 12, wherein
a thickness of the dam portion is 1.4 times or more than a sum of thicknesses of the first organic insulating layer and the second organic insulating layer.

14. The display device of claim 12, further comprising: in the display area,
a cap layer provided on the upper electrode;
a first sealing layer formed of an inorganic insulating material, provided on the cap layer, and contacting the partition;
a first resin layer provided on the first sealing layer;
a second sealing layer formed of an inorganic insulating material and provided on the first resin layer;
a second resin layer provided on the second sealing layer; and
a detection electrode provided on the second sealing layer, covered with the second resin layer, and configured to detect contact or approach of an object to the display area.

15. The display device of claim 14, wherein
the first resin layer is filled between the second organic insulating layer and the dam portion in the surrounding area,
an edge portion of the first resin layer overlaps the dam portion, and
the second sealing layer contacts the inorganic insulating layer at a position overlapping the dam portion.

16. The display device of claim 15, further comprising a detection line provided in the surrounding area, wherein
the detection electrode is electrically connected to the detection line in a contact portion located outside the dam portion.

17. The display device of claim 16, further comprising: in the contact portion,
a first insulating layer spaced apart from the dam portion and formed of same material as that of the first layer;
a terminal provided on the first insulating layer and electrically connected to the detection line; and
a second insulating layer provided on the first insulating layer, covering a portion of the terminal, and formed of same material as that of the second layer, wherein
the second insulating layer is covered with the inorganic insulating layer and the second sealing layer, and
the detection electrode contacts the terminal exposed from the second insulating layer, the inorganic insulating layer, and the second sealing layer.

18. The display device of claim 17, wherein
a thickness of the second insulating layer overlapping the first insulating layer around the terminal is smaller than a thickness of the second layer overlapping the first layer in the dam portion.

19. The display device of claim 1, wherein
the lower portion of the partition comprises a bottom layer provided on the inorganic insulating layer and a stem layer provided between the bottom layer and the upper portion, and
both end portions of each of the bottom layer and the upper portion protrude relative to side surfaces of the stem layer.

20. The display device of claim 1, wherein
an outer edge of at least part of the display area includes a round portion, and
the dam portion has an arcuate curved-line portion along the round portion.
